(19) United States
(12) Patent Application Publication
(10) Pub. No.: US 2025/0311161 A1
(43) Pub. Date: Oct. 2, 2025

(54) VAPOR CHAMBER

(71) Applicant: YUNG-FENG LUNG, Taichung City (TW)

(72) Inventor: YUNG-FENG LUNG, Taichung City (TW)

(21) Appl. No.: 19/092,596

(22) Filed: Mar. 27, 2025

(30) Foreign Application Priority Data
Apr. 2, 2024 (TW) 113112554
Mar. 20, 2025 (TW) 114110551

(51) Int. Cl. H05K 7/20

(52) U.S. Cl. CPC H05K 7/20336

(57) ABSTRACT

A vapor chamber includes a first metal plate, a second metal plate, and a separation structure that is disposed between surfaces of the first and the second metal plate and includes a first chamber wall structure, a second chamber wall structure, an output channel structure, and a recirculation channel structure. A region surrounded by the first chamber wall structure includes a first chamber, and a region surrounded by the second chamber wall structure includes a second chamber. The output channel structure includes a converging section and an accelerating section, in which the converging section is connected to the first chamber, and the accelerating section includes a diverging portion connected to the second chamber. The recirculation channel structure has a plurality of capillary channels. Two ends of each capillary channel are respectively connected to the second outlet of the second chamber and the first inlet of the first chamber.

### BACKGROUND OF THE INVENTION

### Technical Field

The present invention relates generally to a heating spreading device, and more particularly to a vapor chamber.

### Description of Related Art

A vapor chamber is a sheet-like structure, including an upper plate and a lower plate. A vacuum chamber and a mesh structure are provided between the upper plate and the lower plate, and the vacuum chamber is filled with a small amount of liquid. When the lower plate comes into contact with a heat source, the small amount of liquid in the vacuum chamber absorbs a large amount of heat and rapidly boils, evaporating into a vapor. The vapor then condenses into droplets at a distal end. Through the mesh structure, the liquid will be collected back to the vacuum chamber corresponding to the heat source, completing the heat dissipation cycle.

With the continuous advancement in technology, the demand for vapor chambers in various products is increasing. As various electronic products trend towards lighter weights and thinner dimensions, the requirements for miniaturization of vapor chamber dimensions are also rising. Driven by the need for lightweight, vapor chambers are being designed to be thinner, resulting in a narrower distance between the upper plate and the lower plate and decreasing the volume of the vacuum chamber. In the past, the liquid in the vapor chamber was heated and turned into vapor, which diffuses throughout the whole vacuum chamber. However, after the liquid in the thin vapor chamber is heated and turns into vapor, the vapor cannot effectively diffuse throughout the vacuum chamber due to the vacuum chamber's narrowness and backpressure effect, resulting in thin vapor as the vapor moves away from the heat source. That is, for the thin vapor chamber, only the part close to the heat source operates normally, while the rest part thereof cannot dissipate heat effectively, leading to a significant drop in the efficiency of heat dissipation.

It can be seen that improving the vapor chamber for heat dissipation efficiency is an urgent issue for various manufacturers.

### BRIEF SUMMARY OF THE INVENTION

In view of the above, the present invention provides a vapor chamber to improve dissipation efficiency.

The present invention provides a vapor chamber including a first metal plate, a second metal plate, and a separation structure. The first metal plate has a surface, and the second metal plate has a surface. A periphery of the second metal plate and a periphery of the first metal plate are joined together, and the surface of the second metal plate faces the surface of the first metal plate. The separation structure is disposed between the surface of the first metal plate and the surface of the second metal plate.

The separation structure includes a first chamber wall structure, a second chamber wall structure, an output channel structure, and a recirculation channel structure.

A region surrounded by the first chamber wall structure includes a first chamber that has a first outlet and a first inlet.

A region surrounded by the second chamber wall structure includes a second chamber that has a second inlet and a second outlet.

The output channel structure has a first end and a second end, the first end being connected to the first outlet of the first chamber and the second end being connected to the second inlet of the second chamber. The output channel structure includes a converging section and an accelerating section, wherein an end of the converging section forms the first end and is connected to the first outlet of the first chamber, and the other end of the converging section is connected to an end of the accelerating section. The converging section has a width that gradually tapers in a direction away from the first outlet of the first chamber. The accelerating section includes a diverging portion having the second end. The diverging portion has a width that gradually increases in a direction toward the second inlet of the second chamber.

The recirculation channel structure has a plurality of capillary channels. An inlet end of each capillary channel is connected to the second outlet of the second chamber, and an outlet end of each capillary channel is connected to the first inlet of the first chamber.

With the aforementioned design, the vapor chamber includes the first chamber and the second chamber that exchange heat through the output channel structure and the recirculation channel structure. Instead of a single chamber, the design of a dual chamber enables all spaces to facilitate heat dissipation, achieving the intended heat dissipation efficiency of the vapor chamber.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a flow chart of a manufacturing method for a vapor chamber according to a first embodiment of the present invention;

FIG. 2 is a schematic view of the manufacturing method for the vapor chamber according to the first embodiment of the present invention, showing a first pattern screen and a first metal plate printed via the first pattern screen and cured:

FIG. 3 is a schematic view of the manufacturing method for the vapor chamber according to the first embodiment of the present invention, showing a second pattern screen and the first metal plate printed via the second pattern screen and cured:

FIG. 4 is a schematic view of the manufacturing method for the vapor chamber according to the first embodiment of the present invention, showing a third pattern screen and a second metal plate printed via the third pattern screen and cured:

FIG. 5 is a schematic view of the manufacturing method for the vapor chamber according to the first embodiment of the present invention, showing a first mesh and a second mesh respectively placed into a first chamber and a second chamber, and showing the second metal plate assembled with the first metal plate;

FIG. 6 is a schematic view of the manufacturing method for the vapor chamber according to the first embodiment of the present invention, showing a periphery of the second metal plate welded with a periphery of the first metal plate:

FIG. 7 is a sectional view of the structure of various parts of the vapor chamber according to the first embodiment of the present invention, wherein (a) is a sectional schematic view of the first chamber, (b) is a sectional schematic view of an output channel structure, (c) is a sectional schematic view of the second chamber, and (d) is a sectional schematic view of a recirculation channel structure:

FIG. 8 is a schematic view of a flow direction inside the vapor chamber according to the first embodiment of the present invention:

FIG. 9 is a schematic view of the manufacturing method for the vapor chamber according to a second embodiment of the present invention, showing the second pattern screen and the first metal plate printed via the second pattern screen and cured:

FIG. 10 is a schematic view of the manufacturing method for the vapor chamber according to the second embodiment of the present invention, showing the first mesh and the second mesh respectively placed into the first chamber and the second chamber, and showing the second metal plate assembled with the first metal plate:

FIG. 11 is a sectional schematic view of the first chamber of the vapor chamber according to the second embodiment of the present invention:

FIG. 12 is a schematic view of the manufacturing method for the vapor chamber according to a third embodiment of the present invention, showing the first mesh and the second mesh respectively placed into the first chamber and the second chamber, and showing the second metal plate assembled with the first metal plate:

FIG. 13 is a schematic view of the vapor chamber according to a fourth embodiment of the present invention, showing the vapor chamber provided with a cutout region:

FIG. 14 is a schematic view of the manufacturing method for the vapor chamber according to a fifth embodiment of the present invention, showing the first metal plate is 3D printed via a printhead;

FIG. 15 is a schematic view of the manufacturing method for the vapor chamber according to a sixth embodiment of the present invention, showing a liquid absorption sheet placed between the first metal plate and the second metal plate, and showing the second metal plate assembled with the first metal plate:

FIG. 16 is a schematic view of the vapor chamber according to the sixth embodiment of the present invention, wherein the second metal plate is hidden:

FIG. 17 is a schematic view according to the sixth embodiment of the present invention, showing vapor flowing around a support post:

FIG. 18 is a schematic view of the vapor chamber according to a seventh embodiment of the present invention;

FIG. 19 is a schematic view of the vapor chamber according to an eighth embodiment of the present invention:

FIG. 20 is a schematic view of the vapor chamber according to a ninth embodiment of the present invention, wherein the second metal plate is hidden:

FIG. 21 is a schematic view of the vapor chamber according to a tenth embodiment of the present invention, wherein the second metal plate is hidden; and

FIG. 22 is a schematic view of the vapor chamber according to an eleventh embodiment of the present invention, wherein the second metal plate is hidden.

### DETAILED DESCRIPTION OF THE INVENTION

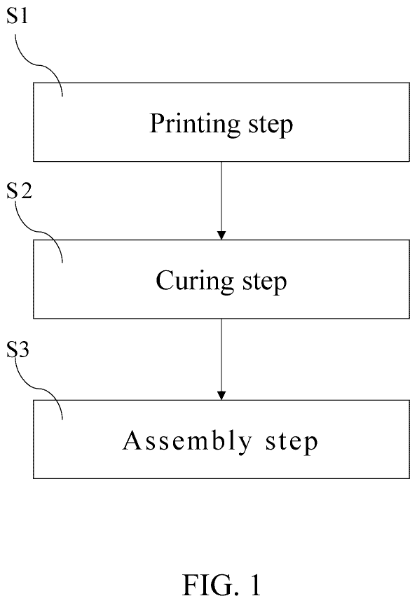

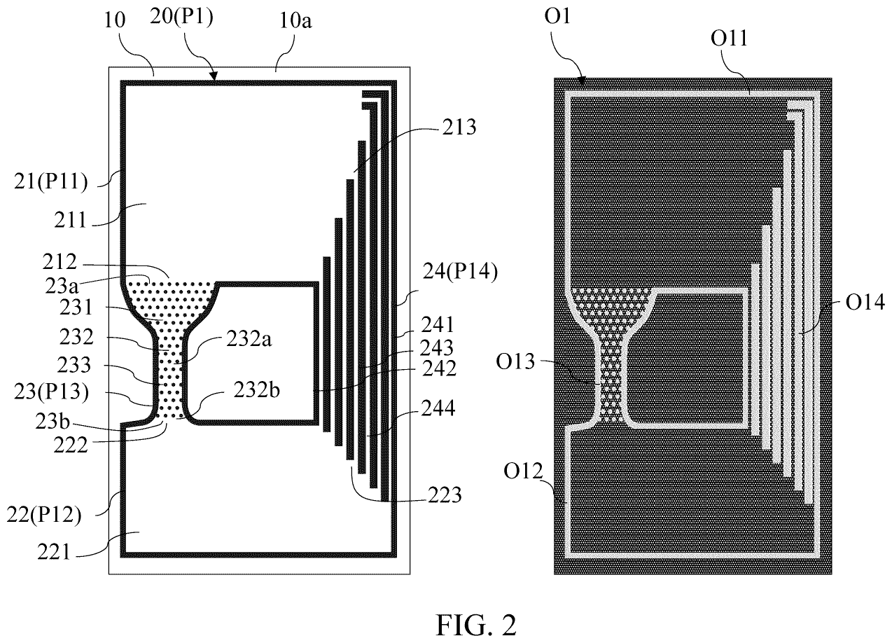

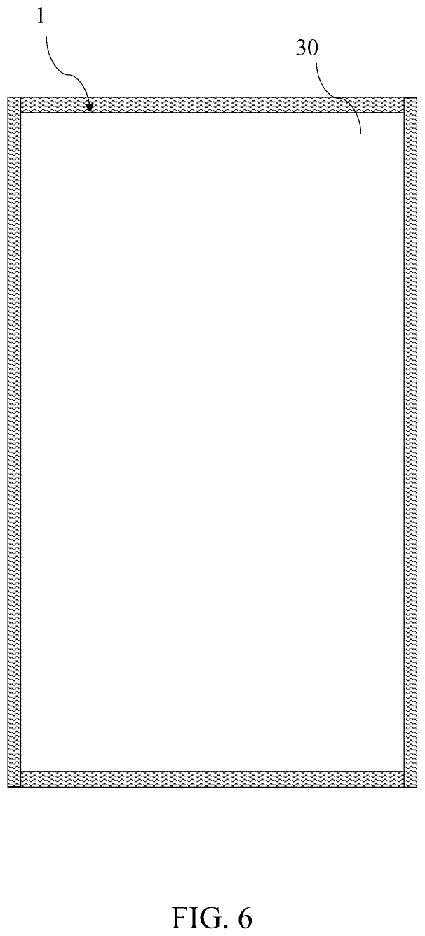

A manufacturing method for a vapor chamber according to a first embodiment of the present invention is illustrated in FIG. 1, wherein the vapor chamber in the current embodiment is manufactured through a printing step S1, a curing step S2, and an assembly step S3. The manufacturing method and the structure of the vapor chamber 1 are subsequently described with reference to FIG. 2 to FIG. 8.

Referring to FIG. 2 to FIG. 4 and FIG. 7, in the manufacturing method for the vapor chamber, a first metal plate 10 and a second metal plate 30 are utilized as substrates for printing. The first metal plate 10 has a thickness defined as a distance D1 ranging from 0.03 mm to 0.1 mm, and the second metal plate 30 has a thickness defined as a distance D2 ranging from 0.03 mm to 0.1 mm. In the current embodiment, the distance D1 of the first metal plate 10 is 0.05 mm and the distance D2 of the second metal plate 30 is 0.05 mm, wherein the first metal plate 10 and the second metal plate 30 are respectively exemplified by a copper plate, but they are not limited thereto; the first metal plate 10 and the second metal plate 30 may also be stainless steel plates or other types of metal plates.

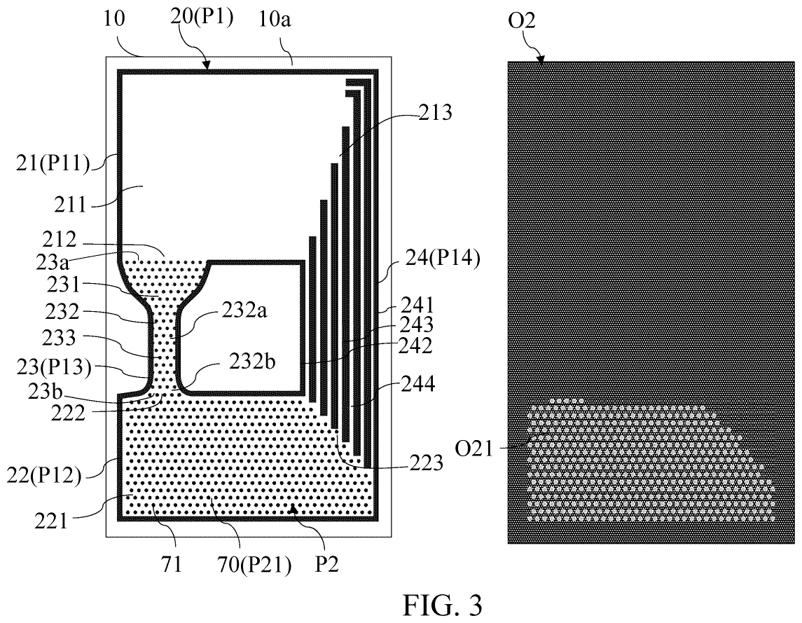

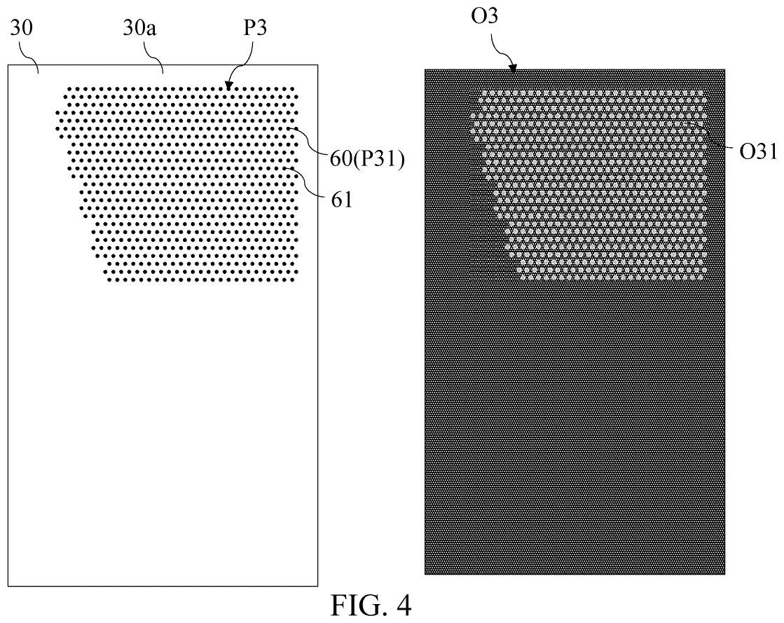

A first pattern screen O1, a second pattern screen O2, and a third pattern screen O3 are selected as screens for printing. As shown in FIG. 2, the first pattern screen O1 includes a first chamber wall mesh region O11, a second chamber wall mesh region O12, an output channel mesh region O13, and a recirculation channel mesh region O14. As illustrated in FIG. 3, the second pattern screen O2 includes a second chamber support structure mesh region O21. As shown in FIG. 4, the third pattern screen O3 includes a first chamber support structure mesh region O31.

A first printing material, a second printing material, and a third printing material are selected as printing materials for printing. The materials of the first printing material, the second printing material, and the third printing material include thermoset plastic materials, such as epoxy resin, phenolic resin, or silicone resin. In an embodiment, the printing materials may also include curable resin, with a preference for a resin that is curable at a temperature below 150° C., such as epoxy resin. The materials of the first printing material, the second printing material, and the third printing material could be the same, or the ingredients thereof could be adjusted according to the purpose. In the current embodiment, the materials of the first printing material, the second printing material, and the third printing material are the same, and all the three include epoxy resin that could be either one-part epoxy resin or two-part epoxy. The one-part epoxy resin includes epoxy resin, diluent, silicon dioxide, and carbon black as additives. Unlike the two-part epoxy resin, the one-part epoxy resin does not cure immediately but hardens after being baked, so heat could be used as a curing means. Silicon dioxide enhances the toughness of the one-part epoxy resin hardened, while carbon black is used for filling and coloring. A diluent is used to reduce the viscosity of the one-part epoxy resin, and examples of the diluent include, but are not limited thereto, benzene and xylene. The two-part epoxy resin cures at room temperature through a cross-linking reaction; therefore, a waiting period at room temperature could serve as a curing means. Regardless of whether it is one-part epoxy resin or two-part epoxy resin, the epoxy resin cured exhibits improved thermal conductivity, which is suitable for thermal conduction in a vapor chamber.

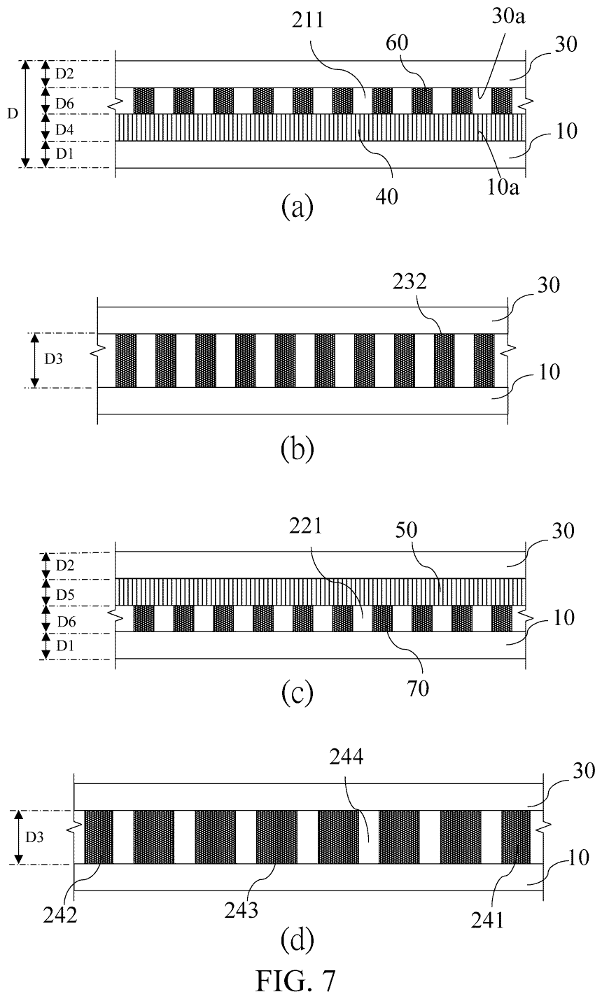

Referring to FIG. 2 and FIG. 7, in the printing step S1, the first printing material is printed on a surface 10a of the first metal plate 10 via the first pattern screen O1, and the first printing material passes through the first chamber wall mesh region O11, the second chamber wall mesh region O12, the output channel mesh region O13, and the recirculation channel mesh region O14, respectively. The first printing material, then, forms a first printed pattern P1 on the surface 10a of the first metal plate 10, the first printed pattern P1 including a first chamber wall pattern P11, a second chamber wall pattern P12, an output channel pattern P13, and a recirculation channel pattern P14.

In the curing step S2, a curing means is applied to the first metal plate 10 that has the first printed pattern P1, such as heating. The first metal plate may be heated in an oven, and the heating temperature and heating time differ based on the amount used and the material dimensions. In general, the heating temperature is controlled below 150° C. to avoid oxidation or deformation of the first metal plate 10 or the second metal plate 30. In the current embodiment, the heating temperature could be, for example, 120° C., and the heating time could be, for example, one hour to cure the first printed pattern P1 to form a separation structure 20, in which the first chamber wall pattern P11 is cured to form a first chamber wall structure 21, the second chamber wall pattern P12 is cured to form a second chamber wall structure 22, the output channel pattern P13 is cured to form an output channel structure 23, and the recirculation channel pattern P14 is cured to form a recirculation channel structure 24. The separation structure 20 includes the first chamber wall structure 21, the second chamber wall structure 22, the output channel structure 23, and the recirculation channel structure 24. The separation structure 20 has a thickness defined as a distance D3 ranging from 0.1 mm to 0.15 mm. In the current embodiment, the distance D3 is 0.1 mm. The aforementioned heating temperature and heating time are merely illustrative: in practice, the heating temperature and heating time could be adjusted based on the characteristics of the printing materials used.

As shown in FIG. 3 and FIG. 7, in the printing step S1, the second printing material is printed on the surface 10a of the first metal plate 10 via the second pattern screen O2, and the second printing material passes through the second chamber wall mesh region O21 so that the second printing material forms a second printed pattern P2 within a region surrounded by the second chamber wall structure 22 on the surface 10a of the first metal plate 10. The second printed pattern P2 includes a second chamber support pattern P21.

In the curing step S2, the first metal plate 10 that has the second printed pattern P2 is heated to cure the second printed pattern P2 so that the second chamber support pattern P21 is cured to form a second chamber support structure 70. The second chamber support structure 70 has a thickness defined as a distance D7 ranging from 0.05 mm to 0.1 mm. In the current embodiment, the distance D7 is 0.05 mm, in which the second printed pattern P2 has a thickness less than a thickness of the first printed pattern P1, and the thickness of the second chamber support structure 70 is less than the thickness of the separation structure 20.

Referring to FIG. 4 and FIG. 7, in the printing step S1, the third printing material is printed on a surface 30a of the second metal plate 30 via the third pattern screen O3, and the third printing material passes through the first chamber support structure mesh region O31 so that the third printing material forms a third printed pattern P3 on the surface 30a of the second metal plate 30. The third printed pattern P3 includes a first chamber support pattern P31.

In the curing step S2, the second metal plate 30 that has the third printed pattern P3 is heated to cure the third printed pattern P3 so that the first chamber support pattern P31 is cured to form a first chamber support structure 60. The first chamber support structure 60 has a thickness defined as a distance D6 ranging from 0.05 mm to 0.1 mm. In the current embodiment, the distance D6 is 0.05 mm, in which the third printed pattern P3 has a thickness less than the thickness of the first printed pattern P1, and the thickness of the first chamber support structure 60 is less than the thickness of the separation structure 20.

In the printing step S1 and the curing step S2, the printing sequences of the first metal plate 10 and the second metal plate 30 are not limited to the aforementioned description. In addition, the heating sequences of the first metal plate 10 and the second metal plate 30 are not limited to the aforementioned description.

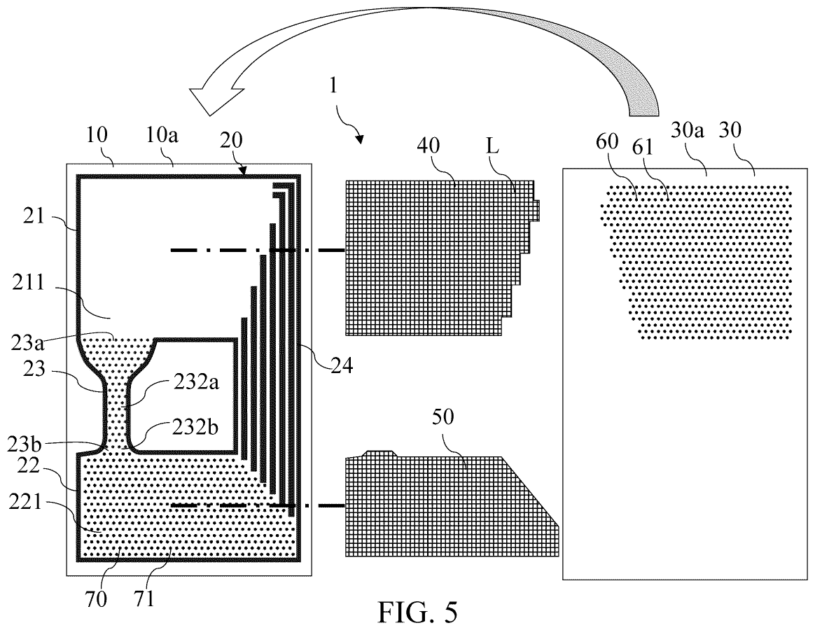

Referring to FIG. 5 to FIG. 7, the manufacturing method for the vapor chamber includes selecting a liquid absorption element. In the current embodiment, the liquid absorption element includes two liquid absorption sheets exemplified by a first mesh 40 and a second mesh 50, respectively. The first mesh 40 and the second mesh 50 serve as mesh structures of the vapor chamber 1. The first mesh 40 has a thickness defined as a distance D4 ranging from 0.03 mm to 0.06 mm, and the second mesh 50 has a thickness defined as a distance D5 ranging from 0.03 mm to 0.06 mm. In the current embodiment, both the first mesh 40 and the second mesh 50 are metal mesh, such as copper mesh: the thickness of the first mesh 40 is 0.045 mm, and the thickness of the second mesh 50 is 0.045 mm. In an embodiment, each liquid absorption sheet could be a fiber material, such as non-woven fabric, but it is not limited thereto; the liquid absorption sheet could also be woven fabric.

In the assembly step S3, the first mesh 40 is provided within a region surrounded by the first chamber wall structure 21 on the first metal plate 10. In the current embodiment, the first mesh 40 absorbs a coolant L and the coolant L could be one of water, alcohols, acetic acid, acetone, or a mixture thereof. Then, the second mesh 50 is provided within a region surrounded by the second chamber wall structure 22, in which the second mesh 50 is located above the second chamber support structure 70. A periphery of the first metal plate 10 and a periphery of the second metal plate 30 are joined together, and the first chamber support structure 60 on the second metal plate 30 corresponds to the region surrounded by the first chamber wall structure 21 on the first metal plate 10. During the peripheral joining process, a space between the first metal plate 10 and the second metal plate 30 is evacuated to a vacuum level or a low-pressure level so that the separation structure 20 abuts against the surface 30a of the second metal plate 30. The joining method could be, but not limited thereto, glueing, welding, and fastening, in which welding could also be laser welding, solid-state welding, roll welding, or diffusion welding, thereby forming the vapor chamber 1. The vapor chamber I has a thickness defined as a distance D that is less than or equal to 0.35 mm, with a preference for the distance D that is less than or equal to 0.2 mm, and more preferably, the distance D is 0.16 mm.

In an embodiment, in the assembly step S3, the first mesh 40 provided within the first metal plate 10 may not absorb the coolant L first, but the coolant L is injected between the first metal plate 10 and the second metal plate 30 during the evacuation process so that the coolant L is absorbed by the first mesh 40.

The vapor chamber 1 in the first embodiment is obtainable by following the aforementioned manufacturing method for the vapor chamber. The structure of the vapor chamber 1 is described below.

Referring to FIG. 5 to FIG. 8, the vapor chamber 1 includes the first metal plate 10, the separation structure 20, the second metal plate 30, the liquid absorption element (the first mesh 40 and the second mesh 50), the first chamber support structure 60, and the second chamber support structure 70. The first metal plate 10 has the surface 10a, the second metal plate 30 has the surface 30a, the periphery of the second metal plate 30 and the periphery of the first metal plate 10 are joined together, and the surface 30a of the second metal plate 30 faces the surface 10a of the first metal plate 10. The separation structure 20 is disposed between the surface 10a of the first metal plate 10 and the surface 30a of the second metal plate 30. In the current embodiment, the separation structure 20 is provided on the surface 10a of the first metal plate 10 and abuts against the surface 30a of the second metal plate 30.

The separation structure 20 includes the first chamber wall structure 21, the second chamber wall structure 22, the output channel structure 23, and the recirculation channel structure 24. The region surrounded by the first chamber wall structure 21 includes the first chamber 211 that has a first outlet 212 and a first inlet 213, in which the first outlet 212 is connected to the output channel structure 23 and the first inlet 213 is connected to the recirculation channel structure 24. The first mesh 40 of the liquid absorption element that absorbs the coolant L is provided within the first chamber 211 and is aligned with the first inlet 213. The first chamber support structure 60 is disposed on the surface 30a of the second metal plate 30 and is located within the first chamber 211. The first chamber support structure 60 abuts against a side where the first mesh 40 faces the second metal plate 30 and is located between the first metal plate 10 and the second metal plate 30. The thickness of the first chamber support structure 60 is less than the thickness of the separation structure 20. The first chamber support structure 60 includes a plurality of support posts exemplified by a plurality of first posts 61. Gaps are provided among the plurality of first posts 61 for the flow of the vapor from the vaporized coolant L. In the current embodiment, each first post 61 is a cylindrical column, but is not limited thereto, the first posts 61 could also be polygonal columns, elliptical columns, or teardrop-shaped columns.

The region surrounded by the second chamber wall structure 22 includes a second chamber 221 that has a second inlet 222 and a second outlet 223. The second inlet 222 is connected to the output channel structure 23, and the second outlet 223 is connected to the recirculation channel structure 24. The second mesh 50 is provided within the second 221 and is aligned with the second outlet 223. The second chamber support structure 70 is located between the first metal plate 10 and the second metal plate 30. The second chamber support structure 70 is provided on the surface 10a of the first metal plate 10 and is located within the second chamber 221. The second chamber support structure 70 abuts against a side where the second mesh 50 faces the first metal plate 10. The thickness of the second chamber support structure 70 is less than the thickness of the separation structure 20. The second chamber support structure 70 includes a plurality of support posts exemplified by a plurality of second posts 71. Gaps are provided among the plurality of second posts 71 for the flow of the vapor from the vaporized coolant L. In the current embodiment, each second post 71 is a cylindrical column, but is not limited thereto, the second posts 71 could also be polygonal columns, elliptical columns, or teardrop-shaped columns.

The output channel structure 23 has a first end 23a and a second end 23b, in which the first end 23a is connected to the first outlet 212 of the first chamber 211 and the second end 23b is connected to the second inlet 222 of the second chamber 221. The output channel structure 23 includes a converging section 231, an accelerating section 232, and a plurality of support posts 233. The converging section 231 and the accelerating section 232 form an accelerating channel. An end of the converging section 231 forms the first end 23a and is connected to the first outlet 212 of the first chamber 211, and the other end of the converging section 231 is connected to an end of the accelerating section 232. The converging section 231 has a width that gradually tapers in a direction away from the first outlet 212. The accelerating section 232 has a width less than the width of the converging section 231, and the other end of the accelerating section 232 is connected to the second inlet 222 of the second chamber 221. The plurality of support posts 233 forms a support structure located between the first metal plate 10 and the second metal plate 30. The plurality of support posts 233 are provided within the converging section 231 and the accelerating section 232. Gaps are provided among the plurality of support posts 233 for the flow of the vapor from the vaporized coolant L. The accelerating section 232 includes a throat 232a and a diverging portion 232b. The throat 232a is connected between the diverging portion 232b and the converging section 231. The diverging portion 232b has the second end 23b, and the diverging portion 232b has a width that gradually increases in a direction toward the second inlet 222 of the second chamber 221. The throat 232a is the location with minimum width between the first end 23a and the second end 23b. In the current embodiment, the throat 232a is an elongated shape with constant width, and the throat 232a has a length greater than a length of the converging portion 232b.

The recirculation channel structure 24 has an outer wall 241, an inner wall 242, and a plurality of channel walls 243. The outer wall 241 is disposed on an outer side of the first metal plate 10, the inner wall 242 is disposed on an inner side of the first metal plate 10, and the plurality of channel walls 243 are disposed between the outer wall 241 and the inner wall 242. The outer wall 241, the inner wall 242, and each channel wall 243 are respectively in contact with the surface 10a of the first metal plate 10 and the surface 30a of the second metal plate 30 to form a plurality of capillary channels 244 among the outer wall 241, the plurality of channel walls 243, and the inner wall 242. An inlet end 244a of each capillary channel 244 is connected to the second outlet 223 of the second chamber 221, and an outlet end 244b of each capillary channel 244 is connected to the first inlet 213 of the first chamber 211. The outlet ends 244b and the inlet ends 244a of the plurality of capillary channels 244 are respectively located close to the first mesh 40 and the second mesh 50, significantly improving the effectiveness of capillary action. The outer wall 241 has a length greater than a length of any of the channel walls 243, the length of any of the channel walls 243 is greater than a length of the inner wall 242, and the length of any of the channel walls 243 gradually decreases in a direction away from the outer wall 241.

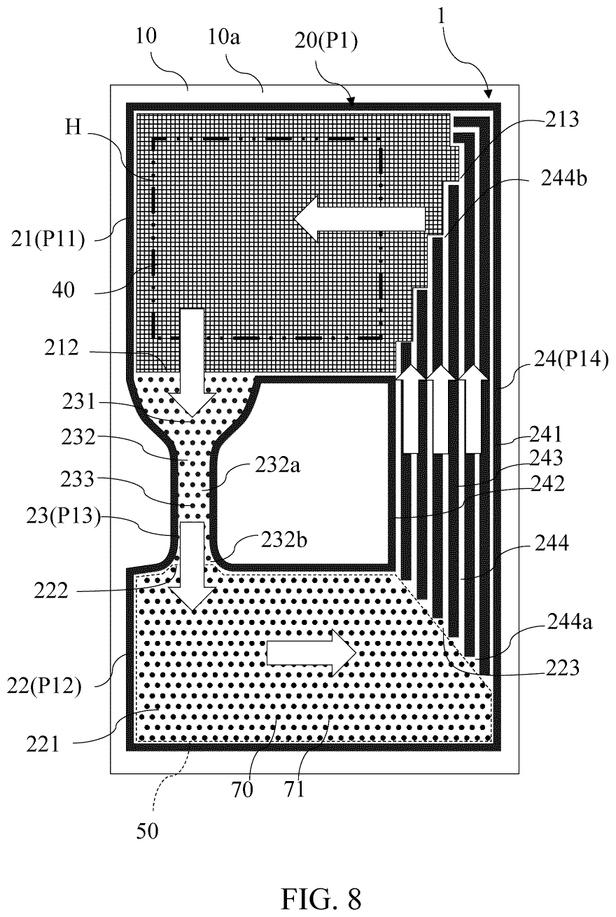

As illustrated in FIG. 8, when the vapor chamber 1 is in use, a part where the first metal plate 10 corresponds to the first chamber 211 is in contact with a heat source H, exemplified by an integrated circuit component. When the first chamber 211 is heated by the heat source H with which the first metal plate 10 is in contact, the coolant L absorbed on the first mesh 40 is heated and boils, evaporating into a vapor that diffuses among the plurality of first posts 61. The vapor diffused will mostly flow into the first outlet 212 that has a greater opening (but not flow into the capillary channels that have extremely narrow openings). After flowing into the output channel structure 23, the vapor flows from the converging section 231 into the accelerating section 232. With the gradual tapering channel width, the vapor accelerates accordingly and rapidly passes through the output channel structure 23 and the second inlet 222, then injects into the second chamber 221. The vapor diffuses throughout the whole second chamber 221 through the gaps of the plurality of the second posts 71. The vapor condenses into droplets upon contact with the second mesh 50. Due to the capillary action of the recirculation channel structure 24, the droplets condensed flow into the second outlet 223 and enter the plurality of capillary channels 244. After flowing along the capillary channels 244 back to the first chamber 211, the droplets diffuse throughout the whole first mesh 40 from the edge thereof, thereby completing the heat dissipation cycle. In the current embodiment, given the fact that the first mesh 40 abuts against the surface 10a of the first metal plate 10, heat generated by the heat source H could be directly transferred to the first mesh 40 via the first metal plate 10, thereby increasing the efficiency of the coolant L boiling and evaporation. A conventional thin vapor chamber is restricted to a chamber with narrow thickness, it is difficult for vapor to diffuse through the whole chamber, resulting in thin vapor as the vapor moves away from the heat source so that only a part of the chamber operates normally to dissipate heat, while the rest part thereof is not involved in the overall dissipation cycle. In the current embodiment, in addition to the first chamber 211, the vapor chamber 1 further has the second chamber 221, the output channel structure 23, and the recirculation channel structure 24. The gaps among the support posts 233 of the output channel structure 23 have a height greater than a height of the gaps among the first posts 61 of the first chamber 211 so that the vapor flows from the first chamber 211 into the output channel structure 23 more easily and, via the output channel structure 23, flows from the first chamber 211 into the second chamber 221. The second chamber 221 adequately utilizes the whole space to facilitate heat dissipation so that the vapor is able to move away from the heat source H and the droplets condensed could be guided back to the first chamber 211 via the recirculation channel structure 24.

Alternatively, in addition to contacting the heat source H with the part where the first metal plate 10 corresponds to the first chamber 211, a part where the second metal plate 30 corresponds to the first chamber 211 could be used to contact with the heat source H.

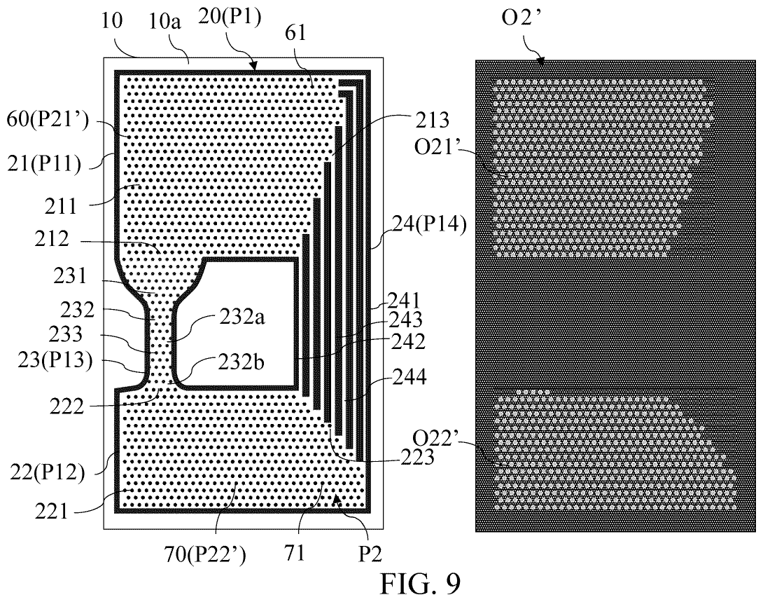

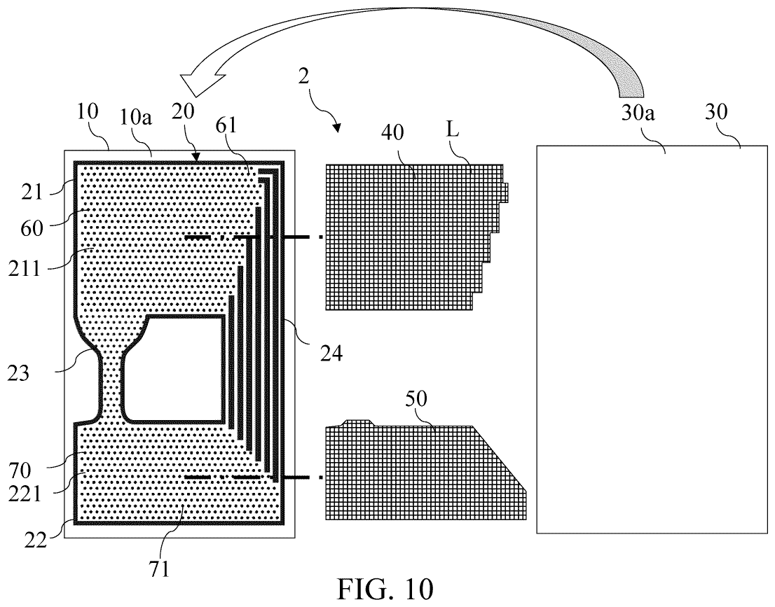

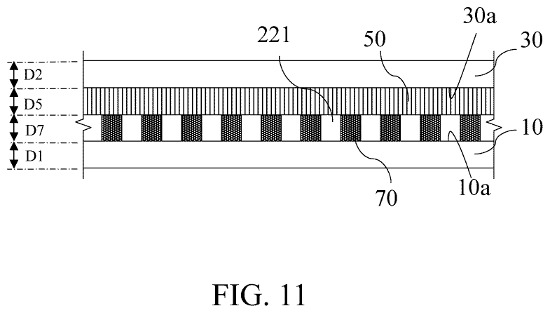

A manufacturing method for a vapor chamber according to a second embodiment of the present invention is illustrated in FIG. 9 to FIG. 11, wherein the second embodiment differs from the first embodiment in that only the first pattern screen O1 and a second pattern screen O2′ are required, and the third pattern screen O3 is not required. The printing process of the first pattern screen O1 is the same as the aforementioned, and will not be repeated herein. The printing process of the second pattern screen O2′ is described below.

In the printing step S1, the second printing material is printed on the surface 10a of the first metal plate 10 via the second pattern screen O2′, and the second printing material respectively passes through a first chamber support structure mesh region O21′, a second chamber support structure mesh region O22′ so that the second printing material forms a second printed pattern P2′ within a region surrounded by the first chamber wall structure 21 and a region surrounded by the second chamber wall structure 22 on the surface 10a of the first metal plate 10. The second printed pattern P2′ includes the first chamber support pattern P21′ and the second chamber support pattern P22′.

In the curing step S2, the first metal plate 10 that has the second printed pattern P2′ is heated to cure the second printed pattern P2′ so that the second chamber support pattern P21 is cured to form the first chamber support structure 60 and the second chamber support pattern P22′ is cured to form a second chamber support structure 70.

In the assembly step S3, the first mesh 40 is provided within a region surrounded by the first chamber wall structure 21 on the first metal plate 10. The first mesh 40 is located above the first chamber support structure 60 and absorbs the coolant L. Then, the second mesh 50 is provided within a region surrounded by the second chamber wall structure 22, in which the second mesh 50 is located above the second chamber support structure 70. By glueing, welding, or fastening, the periphery of the first metal plate 10 and the periphery of the second metal plate 30 are joined together, and the space between the first metal plate 10 and the second metal plate 30 is evacuated to a vacuum level so that the separation structure 20 abuts against the surface 30a of the second metal plate 30, thereby forming a vapor chamber 2. In the second embodiment, only two screens are utilized, which simplifies and accelerates the manufacturing process compared to the first embodiment.

The vapor chamber 2 in the second embodiment is obtainable by following the aforementioned manufacturing method for the vapor chamber. The structure of the vapor chamber 2 is described below.

Referring to FIG. 9 to FIG. 11, the second embodiment differs from the first embodiment in that the first chamber support structure 60 disposed on the surface 10a of the first metal plate 10 is located within the first chamber 211 and abuts against a side where the first mesh 40 faces the first metal plate 10.

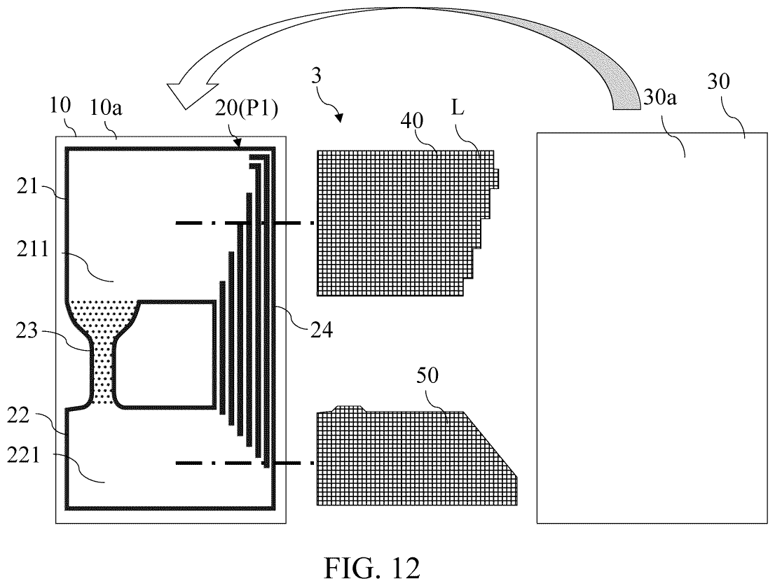

A manufacturing method for a vapor chamber according to a third embodiment of the present invention is illustrated in FIG. 12, wherein the third embodiment differs from the first embodiment in that only the first pattern screen O1 is required, and the second pattern screen O2 and the third pattern screen O3 are not required. The printing process of the first pattern screen O1 is described below.

In the printing step S1, the first printing material is printed on the surface 10a of the first metal plate 10 via the first pattern screen O1 so that the second printing material forms a first printed pattern P1 on the surface 10a of the first metal plate 10.

In the curing step S2, the first metal plate 10 that has the first printed pattern P1 is heated so that the first printed pattern P1 is cured to form the separation structure 20. The separation structure 20 includes the first chamber wall structure 21, the second chamber wall structure 22, the output channel structure 23 and the recirculation channel structure 24.

In the assembly step S3, the first mesh 40 is provided within the region surrounded by the first chamber wall structure 21 on the first metal plate 10, and the first mesh 40 absorbs the coolant L. Then, the second mesh 50 is provided within the region surrounded by the second chamber wall structure 22. By glueing, welding, or fastening, the periphery of the first metal plate 10 and the periphery of the second metal plate 30 are joined together, and the space between the first metal plate 10 and the second metal plate 30 is evacuated to a vacuum level so that the separation structure 20 abuts against the surface 30a of the second metal plate 30, thereby forming a vapor chamber 3. In the third embodiment, only one screen is utilized, which simplifies and accelerates the manufacturing process compared to the first embodiment.

The vapor chamber 3 in the third embodiment is obtainable by following the aforementioned manufacturing method for the vapor chamber. The structure of the vapor chamber 3 is described below.

Referring to FIG. 12, the vapor chamber 3 according to the third embodiment of the present invention differs from the first embodiment in that the vapor chamber 3 does not have the first chamber support structure 60 and the second chamber support structure 70. In the current embodiment, both the first mesh 40 and the second mesh 50 function as a mesh structure and a support structure.

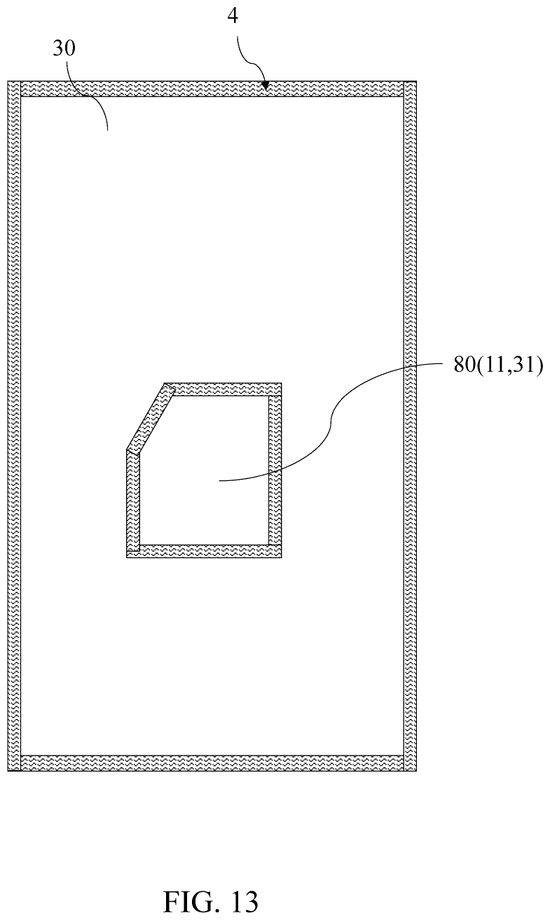

A manufacturing method for a vapor chamber according to a fourth embodiment of the present invention is illustrated in FIG. 13, wherein the fourth embodiment differs from the first embodiment in that the first metal plate 10 further include a first cutout region 11 and the second metal plate 30 further include a second cutout region 31. By using methods, such as glueing, welding, or fastening, during the assembly process, the periphery of the first metal plate 10 and the periphery of the second metal plate 30 are joined together, and a periphery of the second cutout region 31 and a periphery of the first cutout region 11 are correspondingly joined together, thereby forming a cutout region 80.

The vapor chamber 4 in the fourth embodiment is obtainable by following the aforementioned manufacturing method for the vapor chamber. The structure of the vapor chamber 4 is described below.

Referring to FIG. 13, the vapor chamber 4 according to the fourth embodiment of the present invention differs from the first embodiment in that the first metal plate 10 further includes the first cutout region 11 surrounded by the first chamber wall structure 21, the second chamber wall structure 22, the output channel structure 23, and the recirculation channel structure 24, and the second metal plate 30 further includes the second cutout region 31 corresponding to the first cutout region 11. The periphery of the second cutout region 31 and the periphery of the first cutout region 11 are correspondingly joined together, thereby forming the cutout region 80. In the current embodiment, by removing a part of the metal plate within the cutout region 80, the vapor chamber 4 becomes lighter, achieving lightweight effectiveness.

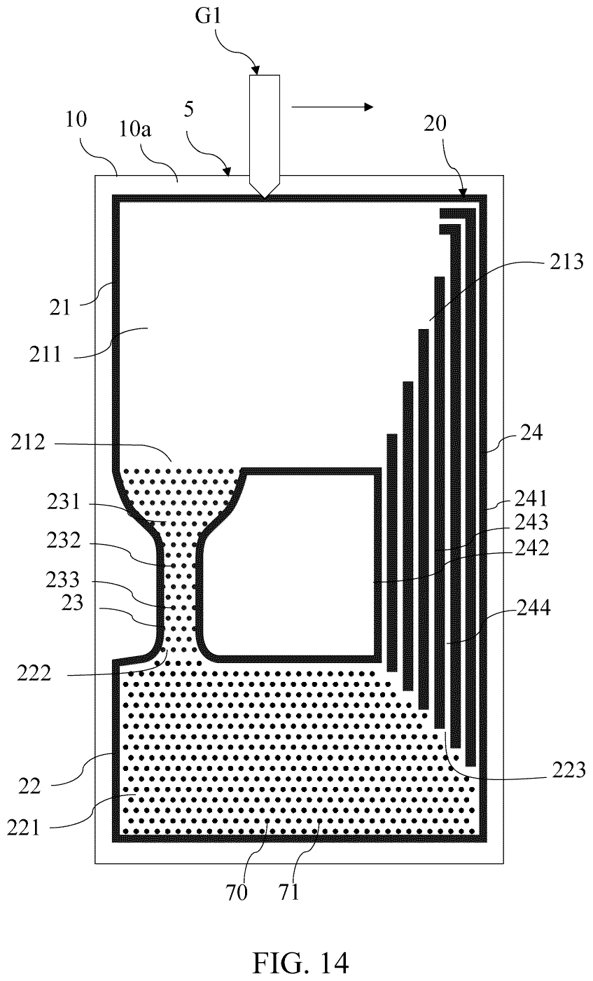

A manufacturing method for a vapor chamber according to a fifth embodiment of the present invention is illustrated in FIG. 14, wherein the fifth embodiment differs from the first embodiment in that, instead of screen printing, the fifth embodiment utilizes a printing method, such as 3D printing. A printhead G1 prints patterns of the separation structure 20, the first chamber support structure 60, and the second chamber support structure 70 on the first metal plate 10 and/or the second metal plate 30 of the vapor chamber 5, then the same effect could be achieved after the assembly step.

The vapor chamber 5 in the fifth embodiment is obtainable by following the aforementioned manufacturing method for the vapor chamber. The structure of the vapor chamber 5 is described below.

Referring to FIG. 14, the vapor chamber 5 according to the fifth embodiment of the present invention differs from the first embodiment in that, compared to traditional printing methods, 3D printing enables the creation of more complex geometric structures and fine-tuning at detailed levels, facilitating flexibility in operation.

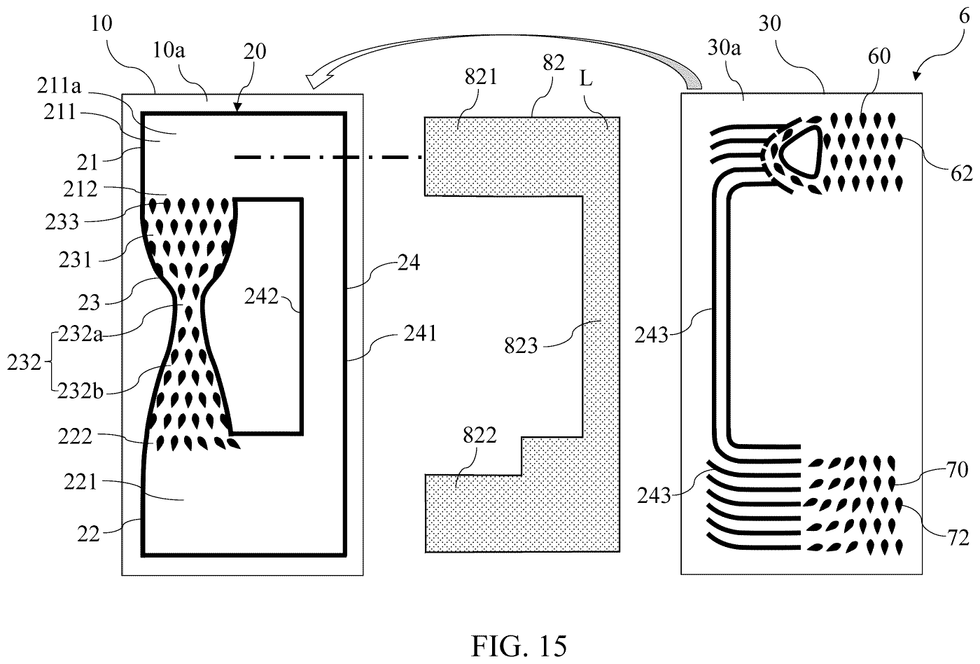

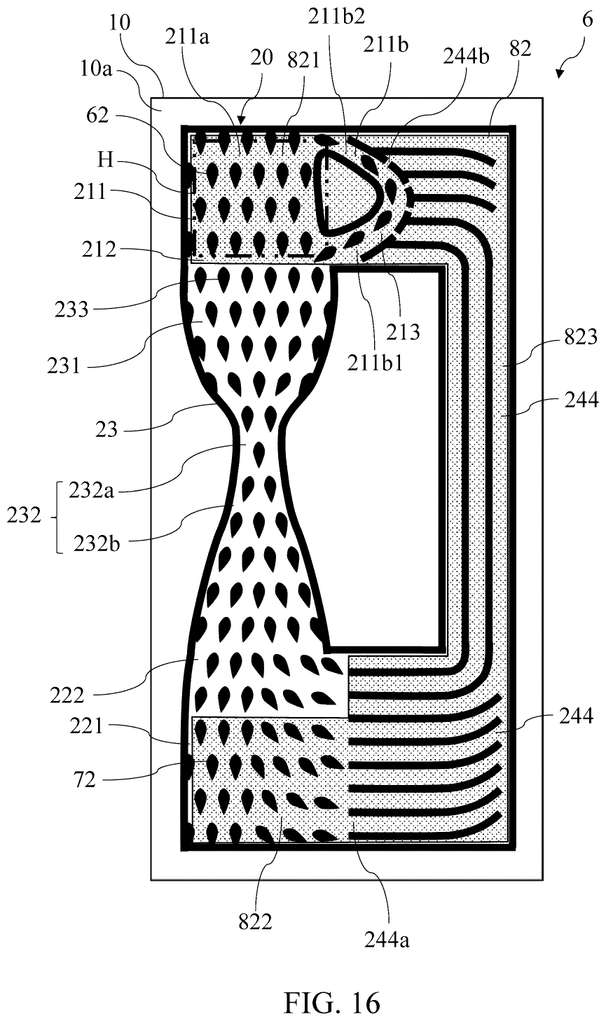

A vapor chamber 6 according to a sixth embodiment of the present invention is illustrated in FIG. 15 to FIG. 17, wherein the vapor chamber 6 has a structure almost the same as the structure in the first embodiment, except that the patterns formed on the first metal plate 10 and the second metal plate 30 are different from the patterns formed in the first embodiment. More specifically, in the current embodiment, the first chamber wall structure 21, the second chamber wall structure 22, the output channel structure 23, and the outer wall 241 and the inner wall 242 of the recirculation channel structure 24 of the separation structure 20 are disposed on the surface 10a of the first metal plate 10, while the first chamber support structure 60, the second chamber support structure 70, and the channel walls 243 of the recirculation channel structure 24 are disposed on the surface 30a of the second metal plate 30.

Additionally, the liquid absorption element in the current embodiment is a liquid absorption sheet 82 that is provided within the first chamber 211, the second chamber 221, and the plurality of capillary channels 244 of the recirculation channel structure 24. The liquid absorption sheet 82 includes a first section 821, a second section 822, and a third section 823, in which the third section 823 is connected to the first section 821 and the second section 822. The first section 821 is provided within the first chamber 211, the second section 822 is provided within the second chamber 221, and the third section 823 is provided within the capillary channels 244 of the recirculation channel structure 24. The liquid absorption sheet 82 is a fiber material. In the current embodiment, the liquid absorption sheet 82 is non-woven fabric, but it is not limited thereto, the liquid absorption sheet 82 could also be woven fabric. In an embodiment, the liquid absorption sheet 82 could also be metal mesh, such as copper mesh.

The widths of the first chamber support structure 60, the second chamber support structure 70, and the plurality of channel walls 243 of the recirculation channel structure 24, which are provided on the surface 30a of the second metal plate 30, are less than the widths of the first chamber wall structure 21, the second chamber wall structure 22, the output channel structure 23, and the outer wall 241 and the inner wall 242 of the recirculation channel structure 24, which are provided on the surface 10a of the first metal plate 10. In this way, the liquid absorption sheet 82 is configured to be accommodated within the space defined by the surface 10a of the first metal plate 10, the first chamber support structure 60, the second chamber support structure 70, and the channel walls 243 of the recirculation channel structure 24.

Compared to the first embodiment, in the current embodiment, the length of the throat 232a in the accelerating section 232 of the output channel structure 23 is shorter. A portion of the accelerating section 232, downstream of the throat 232a, directly forms the diverging portion 232b. The width of the diverging portion 232b gradually increases in the direction toward the second inlet 222 of the second chamber 211. In the current embodiment, the converging section 231 has a length less than the length of the diverging portion 232b. A degree of gradual tapering in the converging section 231 is sharper relative to a degree of gradual widening in the diverging portion 232. In this way, the vapor in the first chamber rapidly concentrates toward the throat 232a of the accelerating section 232, then the vapor accelerates in the diverging portion 232b of the accelerating section 232 and rapidly moves to the second chamber 221.

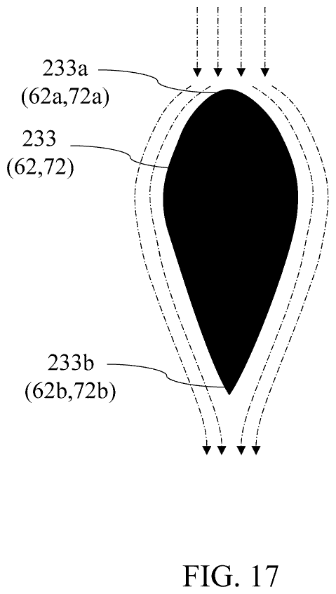

As shown in FIG. 17, in the current embodiment, the plurality of support posts 233 of the support structure of the output channel structure 23 are teardrop-shaped columns, wherein each support post 233 has a rounded end 233a and a tip end 233b, the rounded end 233a oriented toward the first chamber 211 and the tip end 232b oriented toward the second chamber 211. In this way, when flowing through the converging section 231 and the accelerating section, the vapor flows along a peripheral surface of each support 233, from the rounded end 233a to the tip end 233b thereof. The vapor does not exhibit turbulence easily downstream of the tip end 233b, effectively avoiding the velocity reduction of the vapor due to the turbulence, achieving a smoother flow of the vapor or the coolant.

Each support post 62 of the first chamber support structure 60 and each support post 72 of the second chamber support structure 70 are teardrop-shaped columns. The tip end 62b of each support post 62 of the first chamber support structure 60 is oriented toward the converging section 231 of the output channel structure 23. The rounded end 72a of each support post 72 of the second chamber support structure 70 is oriented toward the accelerating section 232 of the output channel structure 23. Each support post 62 of the first chamber support structure 60 and each support post 72 of the second chamber support structure 70 also contribute to achieving a smoother flow of the vapor or the coolant.

In the current embodiment, the first chamber 211 includes a main chamber 211a and a branch channel 211b. The main chamber 211a has the first outlet 212. The branch channel 211b is located on a side of the main chamber 211a and is connected to the outlet ends 244 of the plurality of capillary channels 244. The first inlet 213 of the first chamber 211 is provided between two ends of the branch channel 211b. The plurality of support posts 62 of the first chamber support structure 60 and the plurality of the support posts 72 of the second chamber support structure 70 are distributed throughout the main chamber 211 a and the branch channel 211b.

With the aforementioned structure, the heat source H mainly corresponds to the main chamber 211a of the first chamber 211. The vapor, formed by the heated coolant L boiling in the main chamber 211a, enters the converging section 231 of the output channel structure 23 and then accelerates to flow out from the accelerating section 232. After the vapor condenses to droplets in the second chamber 221, a part of the droplets condensed is absorbed onto the second section 822 of the liquid absorption sheet 82, penetrates into the third section 823 of the liquid absorption sheet 82, and then penetrates into the first section 821 of the liquid absorption sheet 82. Due to the capillary action of the recirculation channel structure 24, the other part of the droplets condensed enter the plurality of capillary channels 244 and flow back to the first chamber 211 along the capillary channels 244. The configuration of the third section 823 of the liquid absorption sheet 82 in conjunction with the plurality of capillary channels 244 enables an accelerated return of the coolant L to the first chamber 211.

Given the fact that he main chamber 211a of the first chamber 211 is the main heating region and the first outlet 212 has a less resistance than the branch channel 211b, the vapor generated from the main chamber 211a mostly enters the converging section 231 from the first outlet 212 directly, preventing significant amounts of vapor from entering the outlet end 244b of each capillary channel 244, thereby affecting the recirculation of the coolant L. Additionally, one of the two ends of the branch channel 211b, which is closer to the first outlet 212, is defined as a branch inlet end 211b1, and the other one thereof, which is away from the first outlet 212, is defined as a branch outlet end 211b2. The branch inlet end 211b1 has a width greater than a width of the branch outlet end 211b2, and the branch channel 211b has a width that gradually tapers in a direction from the branch inlet end 211b1 to the branch outlet end 211b2. When entering the branch channel 211b from the branch inlet end 211b1, the vapor flows rapidly through the branch channel 211b, resulting in low pressure formation at the first inlet 213. The coolant L at the outlet end 244b of each capillary channel 244 is pulled by the low pressure into the branch channel 211b and then injects into the main chamber 211a from the branch outlet end 211b2, accelerating the coolant L to flow back to the main chamber 211a.

The outlet end 244b of each capillary channel 244 has a width less than a width of the inlet end 244a thereof, preventing the vapor in the first chamber 211 from entering the outlet end 244b of each capillary channel 244, thereby affecting the recirculation of the coolant L.

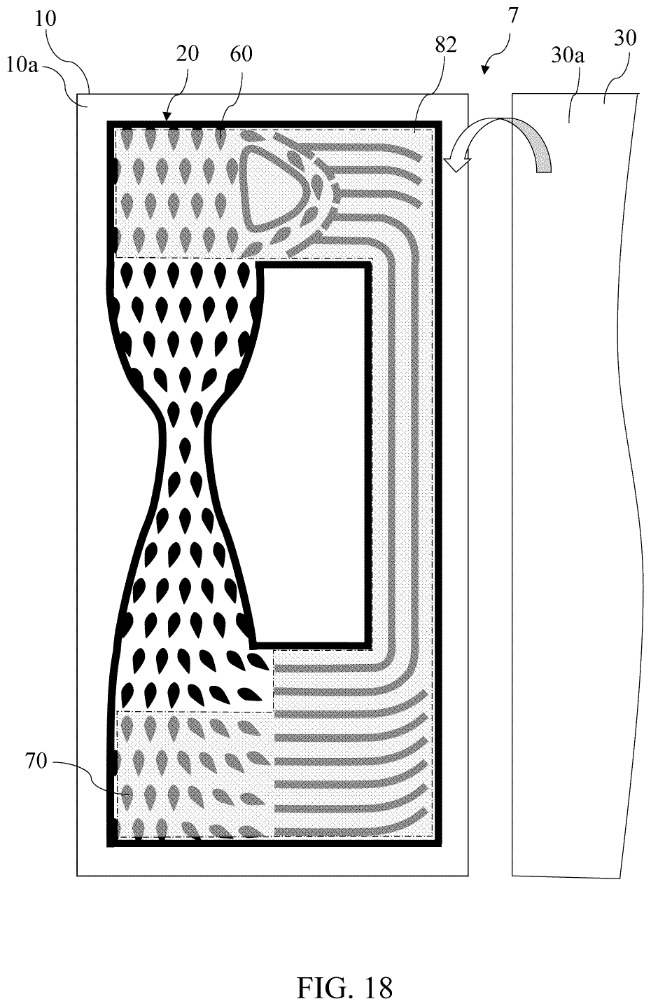

A vapor chamber 7 according to a seventh embodiment of the present invention is illustrated in FIG. 18, wherein the vapor chamber 7 has a structure almost the same as the structure in the sixth embodiment, except that the structures, which include the separation structure 20, the first chamber support structure 60, and the second chamber support structure 70, are disposed on the surface 10 of the first metal plate 10 and have the same thickness. The liquid absorption sheet 82 is located between the surface 30a of the second metal plate 30 and the structures on the surface 10a of the first metal plate 10.

The vapor chamber 7 in the current embodiment achieves the same effect as the sixth embodiment, and therefore, further description is unnecessary.

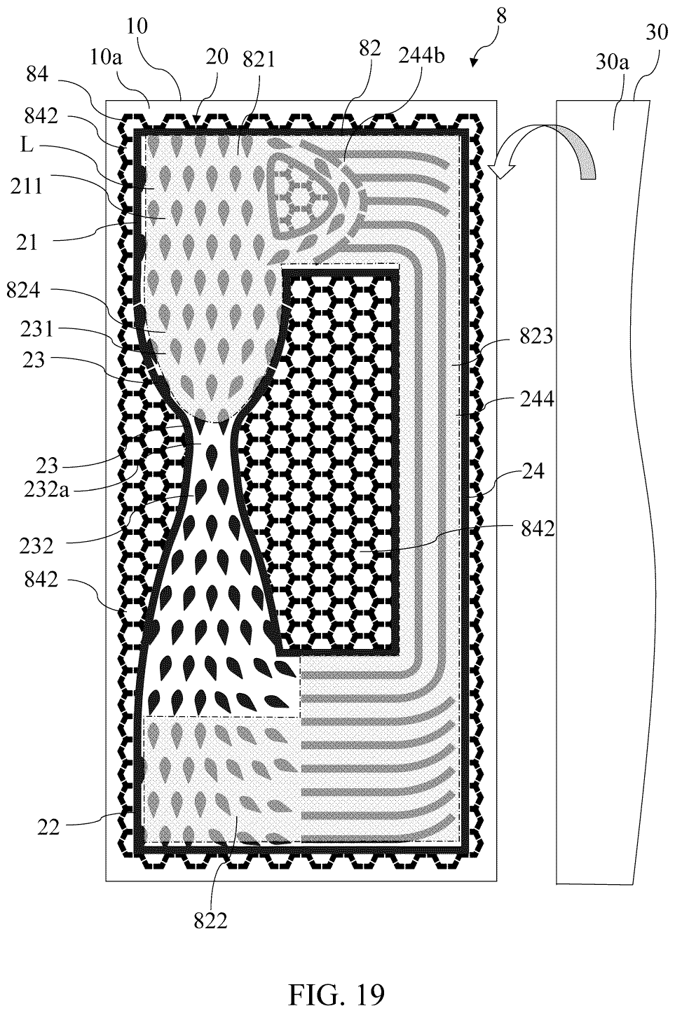

A vapor chamber 8 according to an eighth embodiment of the present invention is illustrated in FIG. 19, wherein the vapor chamber 8 has a structure almost the same as the structure in the seventh embodiment, except that the liquid absorption sheet 82 further includes a fourth section 824 connected to the first section 821 and provided within the converging section 231 of the output channel structure 23. If the vapor generated in the first chamber 211 pushes a part of the coolant L toward the converging section 231 of the output channel structure 23, the fourth section 824 of the liquid absorption sheet 82 absorbs the coolant L in the converging section 231 so that the coolant L is collected through the first section 821 back into the first chamber 211 for subsequent heat absorption. In this way, the coolant L accumulation in the converging section 23a or at the throat 232a of the accelerating section 232 is avoided, thus preventing the resistance to vapor flow and preventing the vapor generated in the first chamber 211 from entering the outlet end 244b of each capillary channel 244, thereby affecting the recirculation of the coolant L.

The separation structure 20 further includes a peripheral support structure 84 that is located around a periphery of the first chamber wall structure 21, the second chamber wall structure 22, the output channel structure 23, and the recirculation channel structure 24, and supports the first metal plate 10 and the second metal plate 30. When the thickness of the first metal plate 10 used or the thickness of second metal plate 30 used is thinner, the metal plate is softer accordingly. Without the peripheral support structure 84, when evacuated to the vacuum level or the low-pressure level, the first metal plate 10 and the second metal plate 30 will move relatively close to each other, in which the two surfaces 10a, 30a might also be in contact with each other, leading to a reduced vacuum space or a reduced low-pressure space: under such circumstances, pressure fluctuations caused by the vapor generation are relatively greater, resulting in a drop in the vacuum level and an increase in the boiling point temperature of the coolant L. Conversely, with the peripheral support structure 84 supporting between the surface 10a of the first metal plate 10 and the surface 30a of the second metal plate 30, when evacuated to the vacuum level or the low-pressure level, the vacuum space or the low-pressure space is able to be maintained, leading to fewer pressure fluctuations caused by the vapor generation and a less drop in the vacuum level, reducing the likelihood of a rise in the boiling point temperature of the coolant L, accelerating the coolant L in the first chamber 211 to vaporize to vapor more rapidly.

In the current embodiment, the peripheral support structure 84 has a plurality of chambers 842, wherein the peripheral support structure 84 has a honeycomb arrangement and each chamber 842 is hexagonal, but it is not limited thereto; each chamber 842 could also be circular or polygonal in shape. Two adjacent chambers 842 could be connected to each other to accelerate evacuation to the vacuum level or the low-pressure level, but it is not limited thereto: the two chambers 842 may not be connected to each other. The chambers 842 are not limited to a honeycomb arrangement, but may be arranged in a matrix. Additionally, the peripheral support structure 84 is not limited to the configuration of chambers, but may be a configuration of a plurality of support posts. Optionally, the converging section 231 of the output channel structure 23 is connected to a part of the chambers 842 surrounding the converging section 231, thereby reducing the pressure rise caused by the vapor in the first chamber 211 and the likelihood of a rise in the boiling point temperature of the coolant L.

The peripheral support structure 84 in the current embodiment may also be applied to the aforementioned embodiments.

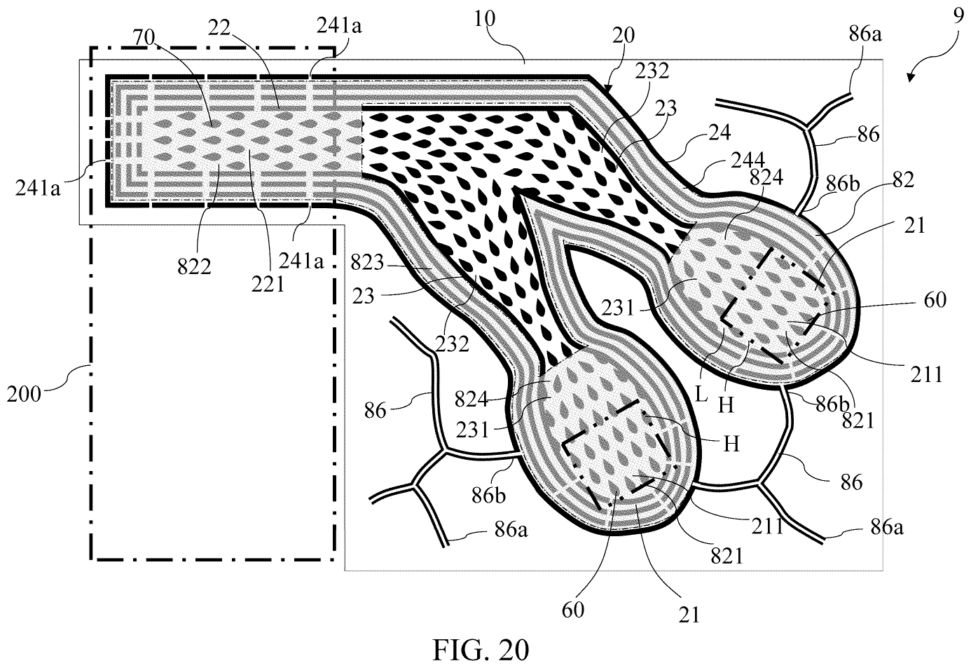

A vapor chamber 9 according to a ninth embodiment of the present invention is illustrated in FIG. 20, wherein the vapor chamber 9 has a structure almost the same as the structure in the seventh embodiment, except that the patterns formed on the first metal plate 10 are different. More specifically, the separation structure 20 includes two first chamber wall structures 21, one second chamber wall structure 22, two output channel structures 23, one recirculation channel structure 24, two first chamber support structures 60, and one second chamber support structure 70. Two first sections 821, the second section 822, and the third section 823 of the liquid absorption sheet 82 are provided within the two first chambers 211, the second chamber 221, and the capillary channels 244 of the recirculation channel structure 24. Optionally, two fourth sections 824 is further provided within the converging section 231 of the two output channel structures 23.

The first chambers 211 of the two first chamber wall structures 21 respectively correspond to two heat sources H at different locations. The second chamber wall structure 22 is located adjacent to a cooling device 200, such as a cooling fan. The second chamber 221 is connected to the accelerating sections 232 of the two output channel structures 23. The two output channel structures 23 respectively accelerate the vapor generated from the two first chambers 211 and guide the vapor to the second chamber 221, enabling the two heat sources H to share a single second chamber 221 for heat dissipation. The cooling device 200 carries away the heat in the second chamber 221, creating the second chamber 221 as a relatively cold region, accelerating the vapor to condense.

In addition, the recirculation channel 24 surrounds each first chamber wall structure 21, the second chamber wall structure 22, and each output channel structure 23. In this way, when the coolant L seeps out of each first chamber wall structure 21, the second chamber wall structure 22, and each output channel structure 23 toward the periphery, the coolant L seeped enters the plurality of capillary channels 244 of the recirculation channel structure 24 and then flows back to each first chamber 211.

In the current embodiment, the separation structure 20 further includes a plurality of peripheral capillary channels 86 that are located on the periphery of the recirculation channel structure 24 and are connected to the outermost one of the capillary channels 244. Each peripheral capillary channel 86 has at least one inlet end 86a and at least one inlet 86b, wherein the inlet end 86a of each peripheral capillary channel 86 has an open configuration, and the outlet end 86b of each peripheral capillary channel 86 is connected to the outer wall 241 of the recirculation channel structure 24. When the coolant L seeps out of the outer wall 241 from the capillary channels 244, the coolant L is absorbed back into the capillary channels 244 due to the capillary action of the corresponding peripheral capillary channel 86, enabling the efficient utilization of the coolant L. The peripheral capillary channels 86 could also be a peripheral support structure to support the first metal plate 10 and the second metal plate 30. In addition, in the current embodiment, the outer wall 241 of the recirculation channel structure 24 is further provided with a plurality of pressure relief vents 241a on a section where the outer wall 241 surrounds the second chamber wall structure 22. The plurality of pressure relief vents 241a that are connected between the second chamber 221 and a surrounding space outside the outer wall 241 are configured for vapor pressure relief inside the second chamber 221. When each heat source H generates a large amount of heat, leading to excessive vapor output to the second chamber 221 and condensation not occurring in time, the vapor could be released through the pressure relief vents 241a to the surrounding space, thus decreasing the pressure inside the second chamber 221 to enable the vapor output from the output channel structure 23 to smoothly flow to the second chamber 221. After the vapor that is released through the pressure relief vents 241a to the surrounding space condenses, the coolant L could be absorbed back into the capillary channels 244 due to the capillary action of the corresponding peripheral capillary channel 86.

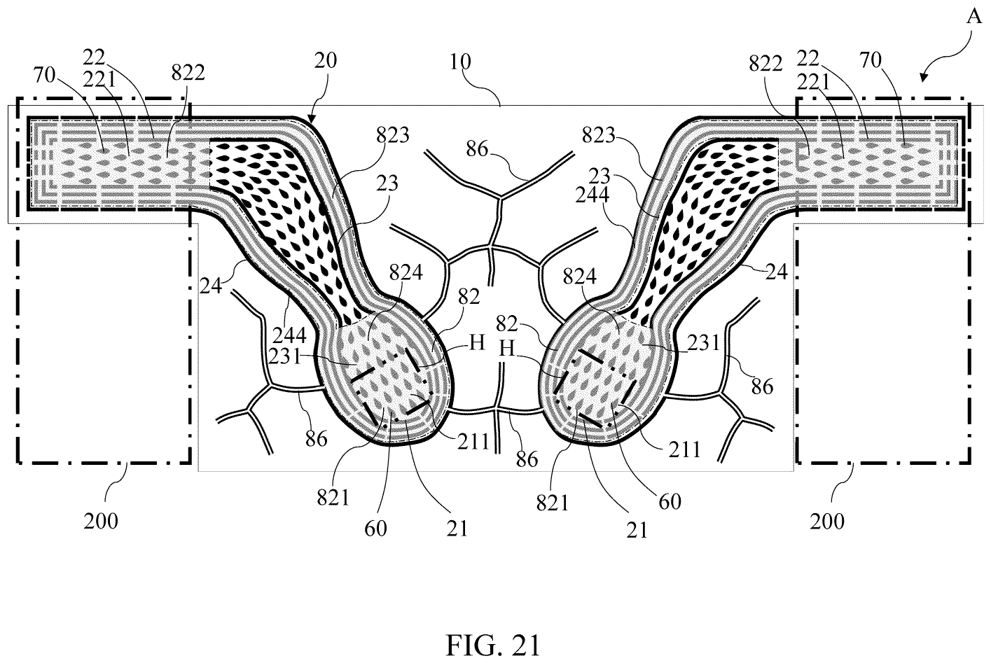

A vapor chamber A according to a tenth embodiment of the present invention is illustrated in FIG. 21, wherein the vapor chamber A has a structure almost the same as the structure in the ninth embodiment, except that the patterns formed on the first metal plate 10 are different. More specifically, the separation structure 20 includes two first chamber wall structures 21, two second chamber wall structures 22, two output channel structures 23, two recirculation channel structures 24, two first chamber support structures 60, and two second chamber support structures 70. That is, the separation structure 20 includes two structures, and each structure includes one first chamber wall structure 21, one second chamber wall structure 22, one output channel structure 23, and one recirculation channel structure 24, wherein each recirculation channel structure 24 surrounds the periphery of the corresponding first chamber wall structure 21, the corresponding second chamber wall structure 22, and the corresponding output channel structure 23.

In the current embodiment, the liquid element of the vapor chamber A includes two liquid sheets 82, and the first section 821, the second section 822, and the third section 823 of each liquid absorption sheet 82 are respectively provided within each first chamber 211, each second chamber 221, and the capillary channels 244 of each recirculation channel structure 24. Optionally, each fourth section 824 is provided within the converging section of each output channel structure 23.

The first chambers 211 of the two first chamber wall structures 21 respectively correspond to two heat sources H at different locations. The two second chamber wall structures 22 are respectively located adjacent to two cooling devices 200 at different locations, enabling the two heat cooling devices 200 to carry away the heat in the two second chambers 221, creating the two second chambers 221 as relatively cold regions, thereby accelerating the vapor to condense.

In the current embodiment, the plurality of peripheral capillary channels 86 are connected to the outermost one of the capillary channels 244 of the recirculation channel structures 24 to collect back the coolant L seeped.

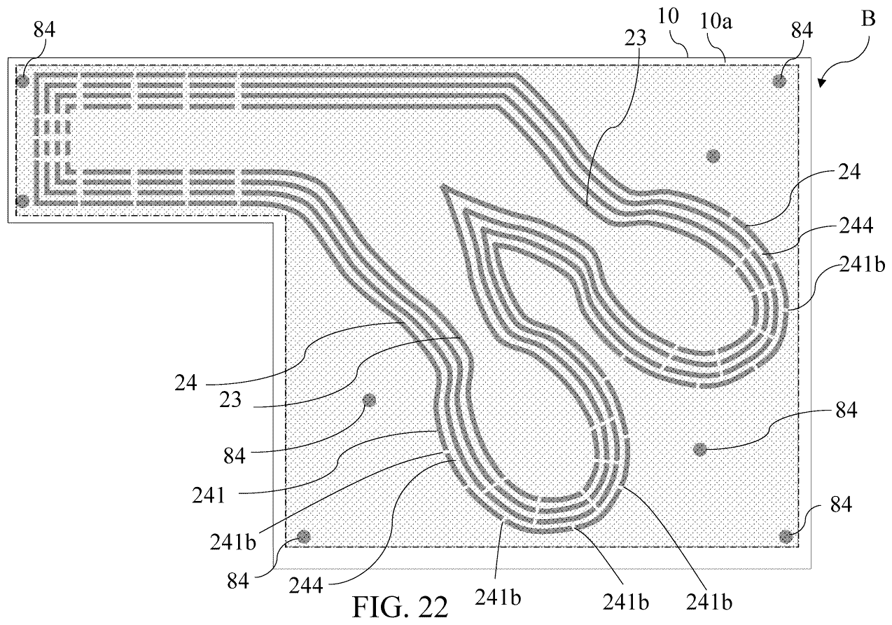

A vapor chamber B according to an eleventh embodiment of the present invention is illustrated in FIG. 22, wherein the vapor chamber B has a structure almost the same as the structure in the ninth embodiment, except that each output channel structure 23 is not provided with the plurality of support posts 233, and the first chamber support structure 60 and the second chamber support structure 70 are not provided. Additionally, instead of the peripheral capillary channel 86, the outer wall 241 of the recirculation channel structure 24 is provided with a plurality of capillary pores 241b on a section where the outer wall 241 surrounds the first chamber wall structure 21. The capillary pores 241b that are connected between the outermost one of the capillary channels 244 and a surrounding space thereof are configured to absorb the coolant L in the surrounding space into the capillary channel 244. Optionally, the surface 10a of the first metal plate 10 is provided with a plurality of peripheral support posts 88 configured to support the space between the first metal plate 10 and the second metal plate 30, and the liquid absorption sheet 82 is configured to fully cover the structures on the surface 10a of the first metal plate 10.

The various designs of the vapor chamber B in the current embodiment could also be applied to the tenth embodiment, for example, each output channel structure 23 is not provided with the plurality of support posts 233; the first chamber support structure 60, the second chamber support structure 70, and the peripheral capillary channels 86 are not provided: the outer wall 241 of the recirculation channel structure 24 is provided with a plurality of capillary pores 241b; and the liquid absorption sheet 82 is configured to fully cover the structures on the surface 10a of the first metal plate 10.

The vapor chamber 9, A, B in the ninth to eleventh embodiments could be applied to large-area heat dissipation for components such as CPU, GPU, battery, and hard drive in devices like laptop computers, computers, and server hosts. Thicker metal plates could be employed for the first metal plate 10 and the second metal plate 30 to prevent warping, and as the metal plates are thicker, the output channel structure 23 may not be provided with the plurality of support posts 233, and the first chamber support structure 60 and the second chamber support structure 70 may not be provided.

The vapor chamber 8, 9, A, B in the eighth to eleventh embodiments could be designed as the vapor chamber 6 in the sixth embodiment, that is, as shown in FIG. 15, the first chamber support structure 60, the second chamber support structure 70, and the plurality of channel walls 243 of the recirculation channel structure 24 are provided on the surface 30a of the second metal plate 30.

In an embodiment, the separation structure 20, the first chamber support structure 60, and the second chamber support structure 70 may be formed by transfer printing on the first metal plate 10 and/or the second metal plate 30, without the limitation to the aforementioned screen printing or printing process. In an embodiment, various structures, such as the separation structure 20, the first chamber support structure 60, and the second chamber support structure 70, may be formed on the first metal plate 10 and/or the second metal plate 30 by machining processing methods like stamping and CNC.

It is noted that the printing materials used in the aforementioned embodiments may also be an ultraviolet (UV) curable resin that includes a resin and a photosensitizer. Upon exposure to UV light, the ultraviolet curable resin transforms from a liquid state to a solid state. In the curing step S2, UV light could be employed as a curing means, that is, UV light emitted from a UV light lamp is used to irradiate various printed patterns on the first metal plate 10 and/or the second metal plate 30, causing the printed patterns to cure and form corresponding structures: consequently, curing could be performed at room temperature without the need for heating. The printing materials used in the aforementioned embodiments may also be high temperature inks that forms the corresponding structures after curing. In the vapor chamber 9, A, B in the ninth to eleventh embodiments, the structures provided on the surface 10a of the first metal plate 10 may be manufactured by plastic injection molding: alternatively, the structures provided on the surface 10a of the first metal plate 10 may be manufactured by integrally die-casting with the first metal plate 10 when the first metal plate 10 is aluminum alloy. In the vapor chamber 9, A, B in the ninth to eleventh embodiments, the liquid absorption element may be manufactured by sintering copper powder, for example, the liquid absorption element may be sintered on the surface 30a of the second metal plate 30 and covers the structures on the surface 10a of the first metal plate 10.

The printing materials in the aforementioned embodiments could also be a mixture of metal powder and a resin. In the curing step S2, high temperature (such as 800° C.) is used to sinter the first metal plate 10 and/or the second metal plate 30 with various printed patterns to vaporize the resin and cure the printed patterns to form a metallic structure with multiple pores.

The liquid absorption element in the aforementioned embodiments could absorb the coolant to achieve the effect of assisting the coolant in flowing back into the first chamber 211. The liquid absorption element may also be provided within the first chamber 211, the converging section 231 and the accelerating section 232 of the output channel structure 23, the second chamber 221, and the capillary channels 244 of the recirculation channel structure 24, and even as the eleventh embodiment, the liquid absorption element extends to the periphery of the aforementioned structures and is fully provided between the first metal plate 10 and the second metal plate 30. In an embodiment, the liquid absorption element may not be provided, and the vapor could still flow from the first chamber 211 to the converging section 231 of the output channel structure 23, then flow to the second chamber 221 through the accelerating section 232 of the output channel structure 23, and condenses into droplets in the second chamber 221. The droplets condensed are guided back to the first chamber 211 via the recirculation channel structure 24.

In addition to using the support posts 233 as the support structures, the converging section 231 and the accelerating section 232 of the output channel structure 23 may also utilize elongated, straight, or curved channel walls as the support structures.

It must be pointed out that the embodiment described above is only a preferred embodiment of the present invention. All equivalent structures which employ the concepts disclosed in this specification and the appended claims should fall within the scope of the present invention.

What is claimed is:

1. A vapor chamber, comprising:
a first metal plate having a surface:
a second metal plate having a surface, a periphery of the second metal plate and a periphery of the first metal plate joined together, the surface of the second metal plate facing the surface of the first metal plate:
a separation structure disposed between the surface of the first metal plate and the surface of the second metal plate, the separation structure including a first chamber wall structure, a second chamber wall structure, an output channel structure, and a recirculation channel structure, wherein:
a region surrounded by the first chamber wall structure includes a first chamber that has a first outlet and a first inlet:
a region surrounded by the second chamber wall structure includes a second chamber that has a second inlet and a second outlet:
the output channel structure has a first end and a second end, the first end being connected to the first outlet of the first chamber and the second end being connected to the second inlet of the second chamber; the output channel structure includes a converging section and an accelerating section, wherein an end of the converging section forms the first end and is connected to the first outlet of the first chamber, and the other end of the converging section is connected to an end of the accelerating section: the converging section has a width that gradually tapers in a direction away from the first outlet of the first chamber; the accelerating section includes a diverging portion having the second end; the diverging portion has a width that gradually increases in a direction toward the second inlet of the second chamber:
the recirculation channel structure has a plurality of capillary channels: an inlet end of each capillary channel is connected to the second outlet of the second chamber, and
an outlet end of each capillary channel is connected to the first inlet of the first chamber.

2. The vapor chamber as claimed in claim 1, wherein the accelerating section includes a throat connected between the diverging portion and the converging section: the throat has a width less than the width of the converging section; the width of the diverging portion gradually increases in the direction from the throat to the second inlet of the second chamber.

3. The vapor chamber as claimed in claim 2, wherein a degree of gradual tapering in the converging section is sharper relative to a degree of gradual widening in the diverging portion.

4. The vapor chamber as claimed in claim 1, wherein the output channel structure includes a support structure located within the converging section and the accelerating section.

5. The vapor chamber as claimed in claim 4, wherein the support structure includes a plurality of support posts: each support post has a rounded end and a tip end, the rounded end oriented toward the first chamber and the tip end oriented toward the second chamber.

6. The vapor chamber as claimed in claim 1, wherein the first chamber includes a main chamber and a branch channel: the main chamber has the first outlet: the branch channel located on a side of the main chamber has two ends respectively connected to the main chamber: the first inlet is provided between the two ends of the branch channel.

7. The vapor chamber as claimed in claim 6, wherein one of the two ends of the branch channel, which is closer to the first outlet, is defined as a branch inlet end, and the other one thereof, which is away from the first outlet, is defined as a branch outlet end: the branch inlet end has a width greater than a width of the branch outlet end, and the branch channel has a width that gradually tapers in a direction from the branch inlet end to the branch outlet end.

8. The vapor chamber as claimed in claim 6, wherein the outlet end of each capillary channel has a width less than a width of the inlet end thereof.

9. The vapor chamber as claimed in claim 1, comprising a first chamber support structure located in the first chamber, wherein the first chamber support structure includes a plurality of support posts: each support post has a rounded end and a tip end, the tip end oriented toward the converging section of the output channel structure.

10. The vapor chamber as claimed in claim 1, comprising a second chamber support structure located in the second chamber, wherein the second chamber support structure includes a plurality of support posts: each support post has a rounded end and a tip end, the rounded end oriented toward the accelerating section of the output channel structure.

11. The vapor chamber as claimed in claim 1, wherein the separation structure includes a peripheral support structure that is located around a periphery of the first chamber wall structure, the second chamber wall structure, the output channel structure, and the recirculation channel structure and supports the first metal plate and the second metal plate.

12. The vapor chamber as claimed in claim 11, wherein the peripheral support structure has a plurality of chambers.

13. The vapor chamber as claimed in claim 1, wherein the recirculation channel structure surrounds the first chamber wall structure, the second chamber wall structure, and the output channel structure.

14. The vapor chamber as claimed in claim 13, wherein the separation structure further includes a plurality of peripheral capillary channels that are located on a periphery of the recirculation channel structure and are connected to the outermost one of the capillary channels.

15. The vapor chamber as claimed in claim 13, wherein the recirculation channel structure has an outer wall provided with a plurality of capillary pores on a section where the outer wall surrounds the first chamber wall structure; the capillary pores are connected to the outermost one of the capillary channels.

16. The vapor chamber as claimed in claim 1, comprising a liquid absorption element at least provided within the first chamber and the second chamber.

17. The vapor chamber as claimed in claim 16, wherein the liquid absorption element includes a liquid absorption sheet having a first section, a second section, and a third section that are respectively provided within the first chamber, the second chamber, and the plurality of capillary channels of the recirculation channel structure.

18. The vapor chamber as claimed in claim 17, wherein the liquid absorption sheet is a fiber material.

19. The vapor chamber as claimed in claim 17, wherein the liquid absorption sheet includes a fourth section provided within the converging section of the output channel structure.

20. The vapor chamber as claimed in claim 16, wherein the liquid absorption element includes two liquid absorption sheets respectively provided within the first chamber and the second chamber.
